(19) United States
(12) Patent Application Publication
(10) Pub. No.: US 2022/0159883 A1
(43) Pub. Date: May 19, 2022

(54) MAGNETIC-FIELD SHIELD WITH DRIVE MAGNET

(71) Applicant: ColdQuanta, Inc., Boulder, CO (US)

(72) Inventors: Evan SALIM, Boulder, CO (US); Hugo LEON, Longmont, CO (US)

(21) Appl. No.: 17/307,716

(22) Filed: May 4, 2021

Related U.S. Application Data
(60) Provisional application No. 63/113,281, filed on Nov. 13, 2020.

(51) Int. Cl. H05K 9/00; G21K 1/00

(52) U.S. Cl. CPC H05K 9/0075; H05K 9/0071; G21K 1/006

(57) ABSTRACT

A magnetic-field shield is used to shield a magneto-optical trap (MOT) in an ultra-high vacuum (UHV) cell from magnetic fields generated by an ion pump used to maintain the UHV. The magnetic-field shield includes an enclosure of ferro-magnetic material that acts to capture portions of the magnetic field generated by the ion pump. However, as the distance between the ion pump and the MOT is less than 6 centimeters, enough of the magnetic field escapes through the ferro-magnetic material, and this leakage could impair the MOT. A drive magnet attached to the yoke redirects magnetic flux, that would otherwise leak out of the magnetic-field shield, along a path within the ferro-magnetic enclosure and away from the MOT.

### BACKGROUND OF THE INVENTION

Cold and ultra-cold matter physics (e.g., optical traps, magneto-optical traps (MOTs), ion traps, laser cooling, and Bose-Einstein Condensates) has spurred demand for compact high vacuum (HV) and ultra-high vacuum (UHV, e.g., from about 10⁻⁹ torr to about 10⁻¹³ torr) systems. At these pressures, the mean free path of a gas molecule is on the order of 40 kilometers (km), so gas molecules typically collide with chamber walls many times before colliding with each other. For this reason, almost all interactions take place on chamber walls and other surfaces within a UHV chamber.

Several vacuum technologies may be used together to establish a UHV. For example, a UHV cell may be baked at high temperatures to release particles prior to establishing UHV. Various pumping technologies can be used to establish UHV. However, a UHV can degrade as particles are introduced intentionally (e.g., as part of an experiment) or unintentionally (e.g., by effusion from or diffusing through vacuum cell walls), so an ongoing pumping technology may be needed to maintain a UHV.

In contrast to other common UHV pumps, such as turbomolecular pumps and diffusion pumps, ion pumps have no moving parts and use no oil. They are therefore clean, need little maintenance, and produce little or no vibrations. Accordingly, ion pumps are currently the most desirable and mature technology for actively maintaining UHV in a compact cell.

A typical ion pump makes use of a Penning trap constituted by an electric field and a magnetic field. The electric field gives rise to free electrons at a cathode and accelerates them toward an anode. A cross product of the magnetic field with the current associated with the accelerating electrons produces a force orthogonal to the electron path. This force diverts the electrons so that they form a swirling cloud. The resulting cloud of swirling electrons ionizes incident molecules, which are then accelerated by the electric fields so that they impact surfaces of getter material, to which the ions are adsorbed. In addition, some molecules, e.g., of hydrogen and noble gases, most significantly, helium, may be absorbed by the getter material. In a “sputter ion pump”, getter material may be liberated (“sputtered”) from the getter surface and then re-deposited, burying sorbed molecules and renewing the getter surface.

### BRIEF DESCRIPTION OF THE DRAWINGS

FIG. 1 is a schematic diagram comparing a magnetic-field shield with a drive magnet with one without a drive magnet.

FIG. 2 is a perspective view of a vacuum-cell system including an ion pump to be shielded by the magnetic-field shield with drive magnet of FIG. 1.

FIG. 3 is a schematic diagram of the ion pump of FIG. 2.

FIG. 4 is a schematic elevation view of the magnetic-field shield with drive magnet of FIG. 1 in position over the ion pump of FIG. 2.

FIG. 5 is a set of three graphs comparing the effectiveness of the magnetic-field shield with drive magnet with the effectiveness of the magnetic-field shield without a drive magnet.

FIG. 6 is a consolidated graph comparing the effectiveness of the magnetic-field shield with drive magnet with the effectiveness of the magnetic-field shield without a drive magnet.

### DETAILED DESCRIPTION

In accordance with the present invention, a magnetic-field shield includes one or more permanent magnets along with ferro-magnetic material so that magnetic fields that would otherwise extend beyond the shield are retained in the ferro-magnetic material. As a result, objects outside the shielding can be better protected from magnetic fields established in the interior of the shield.

Efforts are underway to make more compact UHV systems. UHV systems tend to be incorporated in other systems, the dimensions of which may scale with the size of the UHV system. Smaller UHV systems enable the incorporating systems to be more portable and less expensive. However, as UHV systems become smaller, ion pumps used to maintain UHV conditions become closer to the UHV cell, and the magnetic fields associated with the ion pump can adversely affect delicate fields (e.g., those associated with magneto-optical traps) in the UHV cell. While magnetic shielding around the ion pump magnets can be used help isolate them from the UHV cell, there is typically some leakage. The present invention minimizes this leakage so as to improve the effectiveness of compact UHV systems.

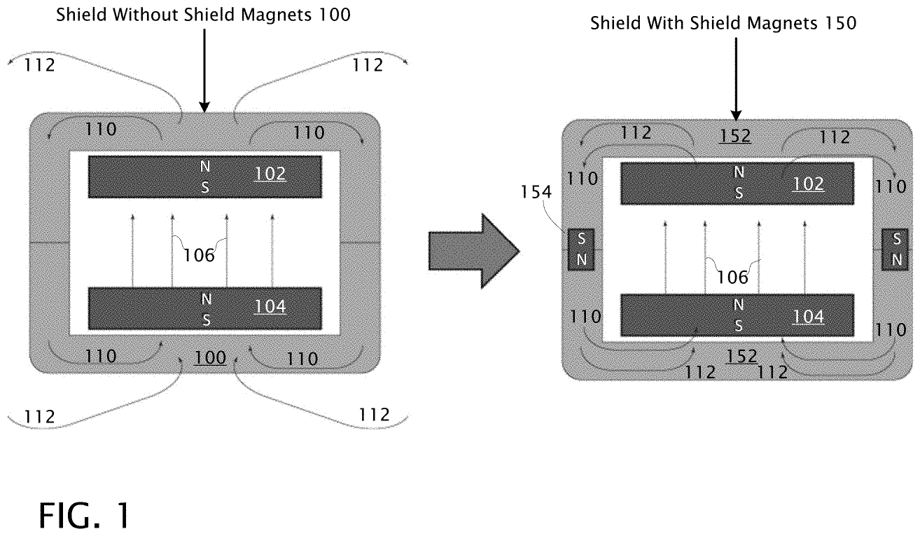

Magnetic shields are shown both with and without a drive magnet set of one or more permanent magnets in FIG. 1. A magnetic shield 100 of ferro-magnetic material encloses a pair of permanent ion-pump magnets 102 and 104 arranged to establish a magnetic field 106 therebetween. Magnetic shield 100 shields its exterior from the magnetic fields associated with permanent ion-pump magnets 102 and 104 by confining magnetic flux 110 to the ferro-magnetic material and limiting the reach of magnetic flux 112 extending out to the exterior of magnetic shield 100. Nonetheless, magnetic flux 112 can be problematic for some applications.

Magnetic shield 150 includes a ferromagnetic enclosure 152 with a drive magnet 154 arranged to tighten the paths of magnetic flux 110 and 112 such that magnetic flux 112 is retained within the ferro-magnetic enclosure 152 of magnetic shield 150. As a result, magnetic flux density 50 mm away due to magnets 102 and 104 is reduced to approximately 5% of that associated with unenhanced shield 100. While magnetic shield 150 includes a single drive magnet, other embodiments use plural drive magnets.

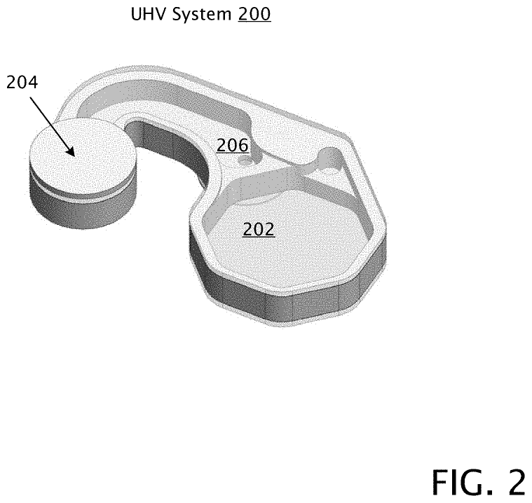

A UHV system 200 is shown in FIG. 2 including a particle manipulation (aka, “work”) chamber 202, an ion pump 204, and a channel 206 from the particle manipulation chamber 202 to ion pump 204. A transparent cover for chamber 202, channel 206 and magnetic shield 150 has yet to be installed. The center-to-center distance between chamber 202 and ion pump 204 is about 5 centimeters (cm), which is less that ten times a diameter of ion pump 204. The separation between chamber 202 and ion pump 204 is about 1 cm. In other embodiments, the separation may be less or more (e.g., up to 2 cm), as can be the center-to-center distance (e.g., from 2 cm to 6 cm) between a chamber and the ion pump.

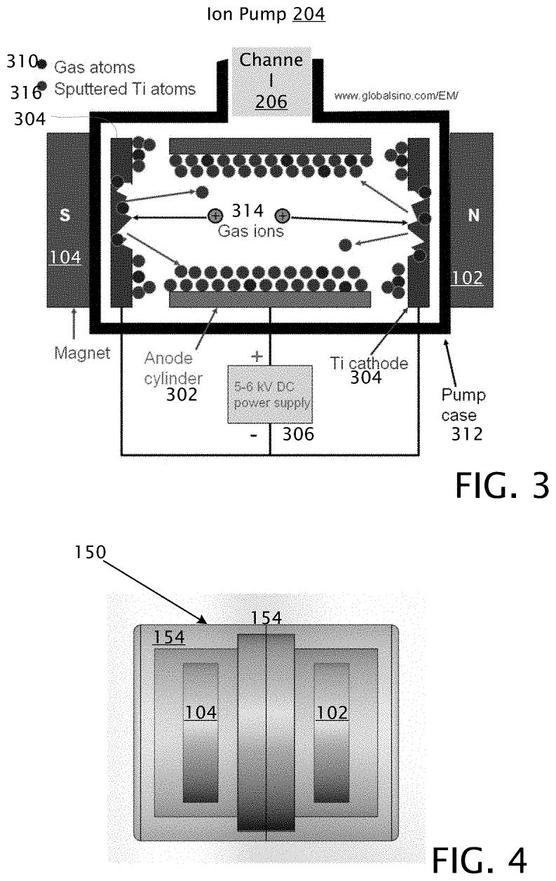

Ion pump 204 is shown in greater detail in FIG. 3 including a cylindrical anode 302, disk-shaped titanium cathodes 304, a power supply 306, and disk-shaped permanent magnets 102 and 104. Gas atoms 310 enter ion pump case 312 of ion pump 204 via channel 206. Gas atoms 310 can include intentionally introduce atoms, typically alkali or alkaline-earth metal atoms. Gas atoms 310 may also include contaminants, e.g., helium atoms that diffused into chamber 202 via walls of UHV cell 200.

Power supply 306 applies a voltage differential, e.g., 5-6 kilovolts (kV) direct current (DC), between anode 302 and cathodes 304. This voltage differential draws electrons from cathodes 304 toward anode 302. Magnetic field 106 (FIG. 1) established by permanent ion-pump magnets 102 and 104 causes the electrons to swirl within anode 302 rather than reach it directly. As a result, the electrons have more time available to ionize gas atoms 310. Some gas atoms (e.g., the alkali atoms) are readily ionized by the electrons to produce gas ions 314. These gas ions are attracted to and are retained by cathodes 304. Other atoms, e.g., helium atoms, are not readily ionized. However, the neutral atoms eventually collide with and are adsorbed to anode and cathode surfaces. Titanium atoms 316, sputtered from cathodes 304, can then bury gas atoms 310 so that they do not desorb and impair the vacuum.

A challenge addressed by the present invention is to prevent magnetic fields produced by ion-pump magnets 102 and 104 from disturbing processes in chamber 202 (FIG. 2). To this end, ion pump 204 is enclosed by magnetic shielding 150 (FIG. 1). As explained with reference to FIG. 1, magnetic-field shield 150 includes ferro-magnetic material arranged to enclose ion pump 204 so that magnetic fields can be confined within the ferromagnetic material so that they do not impact chamber 202. However, as miniaturization efforts have brought sensitive components closer together, the tolerance for leaked magnetic fields has decreased. In accordance with the present invention, the addition of ring-shaped drive magnet 154 to shield 150 enhances the effectiveness of the shielding. As shown in FIG. 4, the interior of drive magnet 154 is parallel to and mid-way between ion-pump magnets 102 and 104. In other embodiments, other configurations of ferro-magnetic material and drive magnets are used.

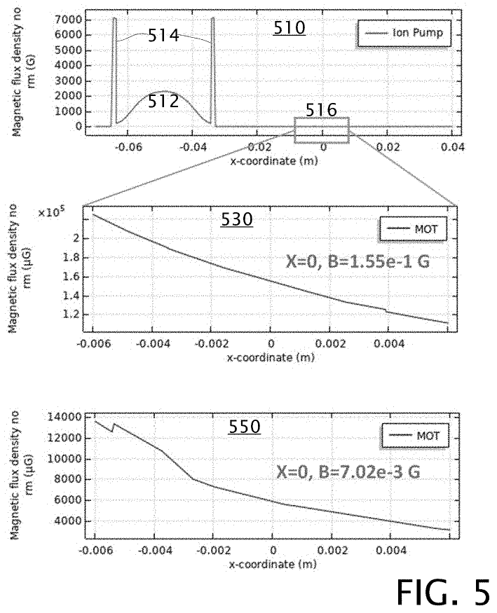

The effectiveness of shield 150 is indicated by the graphs 510, 530, and 550 of FIG. 5. Graph 510 plots magnetic flux density (in Gauss G) versus distance in meters (m). “0” distance marks the center of chamber 202, i.e., the center of a target region to be protected from stray magnetic fields. Distances −0.06 to −0.04 represent distances 6 cm and 5 cm respectively from the target region. This range of distances corresponds to an interior of ion pump 204, which is characterized by a dome-shaped magnetic flux density distribution 512. Magnetic flux density peaks 514 at about −3.5 cm and 6.5 cm corresponds to magnetic flux densities within the ferro-magnetic material of shield 150. The rectangle 516 about 0 distance indicates the distance ranges for both graph 530 and graph 550, which includes a magneto-optical trap requiring magnetic isolation from ion-pump magnets 102 and 104.

Graph 130 represents the magnetic flux density at the MOT when shield 100 (with no drive magnets) is used. At x=0, the magnetic flux density is 1.55×10-1 G or 155 milliGauss (mG). Graph 150 represents the magnetic flux density at magneto-optical trap (MOT) 208 (FIG. 2) when shield 150 (with drive magnet) is used. At MOT 208 (FIG. 2), the magnetic flux density is 7.02×10-3 G or about 7 mG. The ratio of the magnetic flux densities with and without drive magnet 154 is 7/155 or about 4.5%; in other words, drive magnet 154 provides about a 95% improvement in shield effectiveness (over that provided by shield 100) at 5 cm.

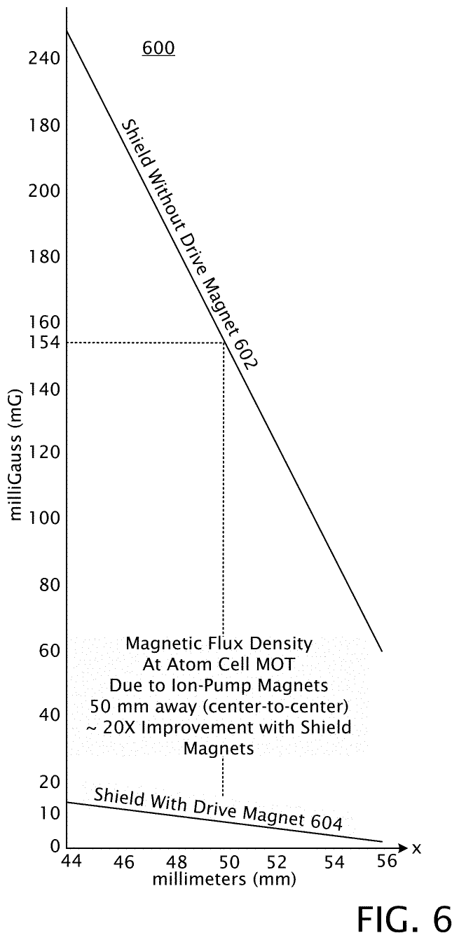

Graph 600 of FIG. 6 compares the shields with and without drive magnet using a common scale for the magnetic flux density. Line 602 shows a relatively strong magnetic field at the MOT for shield 100 (without drive magnet), while line 604 shows a relatively weak magnetic field at the MOT for shield 150 (with drive magnet). This comparison indicates that the drive magnet provides dramatic improvements in shield effectiveness at distances below 6 cm from the ion pump center, and that the improvement in effectiveness increases as the distances decrease (at least down to about 44 mm.)

Herein, “ion pump” refers to any system that removes mobile molecules (including monatomic molecules) from a local (incomplete) vacuum by:

1) ionizing the molecules to yield ions; and 2) immobilizing the ions by sorbing (adsorbing or absorbing) them to a “getter” material. Herein, “molecule” refers to the smallest particle in a chemical element or compound that has the chemical properties of that element or compound. Herein, a ferro-magnetic enclosure defines an interior and exterior even in cases where the enclosure is incomplete in that it is “interrupted”, e.g., to provide a channel to an ion pump.

Herein, any art labeled “prior art”, if any, is admitted prior art; any art not labeled “prior art”, if any, is not admitted prior art. The illustrated embodiments, variations thereupon and modifications thereto are provided for by the present invention, the scope of which is defined by the following claims.

What is claimed is:

1. A magnetic-field shield system comprising:
a ferro-magnetic enclosure defining an interior and an exterior; and
a drive magnet set arranged to redirect magnetic flux density, which would otherwise extend to the exterior, along a path within the ferro-magnetic material and not extending to the exterior, the magnetic flux density being associated with a magnetic field generated in the interior, the drive magnet set including at least one permanent magnet.

2. The magnetic-field shield system of claim 1 wherein the ferro-magnetic enclosure encloses a pair of permanent magnets that collectively generate the magnetic field.

3. The magnetic-field shield system of claim 1 wherein the ferro-magnetic enclosure encloses an ion pump, the ion pump including a pair of permanent magnets that collectively generate the magnetic field.

4. The magnetic-field shield system of claim 1 further comprising an ultra-high vacuum (UHV) cell defining a work chamber, an ion pump, and a channel from the work chamber to the ion pump, the ion pump being located in the interior and the work chamber being located in the exterior, the ion pump including a pair of permanent magnets that collectively generate the magnetic field.

5. The magnetic-field shield system of claim 4 wherein the work chamber includes a trap for ions or neutral atoms, the permanent drive magnet helping the ferro-magnetic enclosure isolate the trap from the magnetic field generated by the pair of permanent magnets.

6. The magnetic-field shield system of claim 5 wherein a distance between the trap and the ion pump is less than 10 times a characteristic diameter of the pumping volume.

7. The magnetic-field shield system of claim 5 wherein a distance between the trap and the ion pump is less than 6 centimeters.
